(19) United States
(12) Patent Application Publication
(10) Pub. No.: US 2024/0268037 A1
(43) Pub. Date: Aug. 8, 2024

(54) ORGANIC SUBSTRATE-BASED WEARABLE PLATFORM AND METHODS FOR ON-BODY SENSING AND DELIVERY OF THERAPEUTICS

(71) Applicant: Takaroa Corporation, Inc., San Diego, CA (US)

(72) Inventor: Ethan M. Devine, San Diego, CA (US)

(21) Appl. No.: 18/431,231

(22) Filed: Feb. 2, 2024

Related U.S. Application Data
(60) Provisional application No. 63/443,119, filed on Feb. 3, 2023.

(51) Int. Cl. H05K 3/46; C08L 1/02; H05K 1/11; H05K 3/00; H05K 3/34

(52) U.S. Cl. CPC H05K 3/4644; C08L 1/02; H05K 1/111; H05K 3/0094; H05K 3/3452; C08L 2203/02; H05K 2201/0137; H05K 2201/09218; H05K 2203/1105; H05K 2203/12; H05K 2203/1333

(57) ABSTRACT

A method for fabricating a printed circuit board comprising preparing a surface of an organic material substrate then depositing conductive traces and at least one conductive pad on the organic material substrate through an additive deposition process. The conductive traces and pads are then heat-treated to create electrically conductive pathways and at least one heat-treated conductive pad. A dielectric material is then deposited through the additive deposition process over a portion of the heat-treated conductive traces to create a dielectric material containing area and a non-dielectric material containing area. The dielectric material containing area is then heat-treated.

### CROSS-REFERENCE TO RELATED APPLICATIONS

This application claims the benefit of U.S. Provisional Patent Application Ser. No. 63/443,119 filed on Feb. 3, 2023, the content of which is hereby incorporated by reference.

### BACKGROUND

Wearable devices, such as fitness trackers and health monitoring systems, should ideally be imperceptible. To this end, they are preferably very thin, conformal to the contours of the skin, and extremely lightweight. While ultra-thin polymer sheets do exist, printing with typically hydrophilic inks on hydrophobic polymer substrates is challenging. Additional issues with breathability and biocompatibility hinder their utility for health-related applications.

In response to these issues, a process was developed to create microbial nanocellulose sheets thinner than 20 μm, resulting in a new material class. See U.S. Pat. No. 9,720,318. These ultrathin sheets present opportunities for various applications, such as for flexible electronics. Microbial nanocellulose is highly chemical and solvent resistant, mechanically strong, water permeable, and biocompatible. Nanocellulose sheets are grown in-situ from microbial broth as millimeter-thick gel layers and can be of any arbitrary size or shape as determined by the growth vat. The gel layers can be laminated onto a wide range of substrates, and upon drying, shrink laterally into microns-thick sheets. These sheets can be easily delaminated from the substrate simply by moistening the film, resulting in a freestanding microns-thick film. Moistening the film does not return it to the gel state; rather, it retains its sheet-like characteristics. The porosity of such nanocellulose sheets makes them amenable to the wicking effect, allowing the absorption of most liquids into the nanocellulose matrix. Other types of flexible, free-standing substrates below 20 μm that contain a porous network are extremely rare and exceedingly difficult to manufacture in bulk. Even in the rarely available cases, the pores in the so-called porous films below 20 μm are actually through-holes that cut directly through both sides of the film, rendering the films more like sieves.

Wearables offer new possibilities in remote health monitoring, allowing for the identification and measurement of various metrics, such as analytes, biomarkers, physical activity, and sleep, as well as real-time, closed loop, controlled delivery of therapeutic treatments based on the aforementioned metrics.

Printed circuit boards (PCBs), whether rigid or flexible, are ubiquitous building blocks for today's electronics, including wearables, yet they have a number of disadvantages. These include being relatively thick and bulky, adding weight and size to finished devices. Moreover, traditional PCBs are polluting to manufacture and dispose of, contributing to harmful emissions and electronic waste during their product life cycle. In most use cases, traditional PCBs also require a housing structure. All of these properties make them less convenient to users and harmful to the environment. This is particularly true for wearable sensors and medical devices, where demands for imperceptibility and biocompatibility are paramount. Thus, there is a need for imperceptible devices that gather biometric data in a less obtrusive and more sustainable way.

A different approach is to use organically-derived, flexible biomaterials, such as bacterial or microbial nanocellulose-a biomaterial grown by fermentation-as a substrate for printed circuits. Nanocellulose is a naturally occurring byproduct grown from strains of bacteria. The end product is a microns-thin, conformal, self-adhering sheet with excellent mechanical strength. Some of bacterial nanocellulose's properties, particularly its lightweight, ultra-thin, translucent, conformal, and porous nature, make it largely imperceptible to the user when worn on the skin. Biocompatible and biodegradable, nanocellulose is eco-friendly and can reduce electronic waste. These properties make bacterial nanocellulose uniquely suited for epidermal-based sensors, where biocompatibility and imperceptibility are of paramount importance.

Electronic devices, including wearables, largely rely on PCBs as their electronics architecture. PCBs require conductive traces, a basic building block for the circuitry, and connections between the mounted electronic components. Traditional PCB fabrication requires substantial amounts of inputs, such as water, electricity, and toxic chemicals, resulting in brittle traces unable to perform under extreme physiological conditions such as flex or strain. Therefore, there is a need in the art for a method of creating single, dual, and multi-layered printed circuits on and under the surface of ecologically friendly materials, such as bacterial nanocellulose.

Other hardware and critical components of conventional biosensors suffer from the same limitations as traditional PCBs, namely bulkiness, lack of eco-friendly and biocompatible properties, as well as difficulty in functionalization for on-body sensing applications. As such, bacterial nanocellulose may be used as a comprehensive platform to create microfluidics layers, electrochemical sensors/transducers, and microneedle arrays to offer robust, interconnected, biosensing platforms that monitor and measure biomarkers, as well as provide treatment via transdermal delivery methods.

### BRIEF DESCRIPTION OF THE DRAWINGS

The drawings and detailed description that follow are intended to be merely illustrative and are not intended to limit the scope of the invention as contemplated by the inventors.

FIG. 1 is a flowchart describing a method for fabricating a single, dual, or multi-layered printed circuit board (PCB) on an organic material substrate, using an extrusion/direct-write or inkjet printing method;

FIG. 2 is a flowchart describing a method for fabricating a single, dual, or multi-layered PCB with an organic material substrate, using an aerosol deposition or screen-printing method;

FIG. 3 is a flowchart describing the method for fabricating and assembling a single-layer PCB with an organic material substrate;

FIG. 4 is a block diagram of a system for a wearable sensor platform;

FIG. 5 is a three-point electrode on a substrate of an organic material, such as bacterial nanocellulose;

FIG. 6 is a bacterial nanocellulose platform with PCB and microneedle array;

FIG. 7 is a bacterial nanocellulose platform with PCB and conductive microneedle array with drug loading;

FIG. 8 is a bacterial nanocellulose platform with PCB and microneedle array with drug loading, and microfluidics layer;

FIG. 9 is a bacterial nanocellulose platform with PCB and microneedle array with drug loading, microfluidics layer, and electrochemical sensor;

FIG. 10 is a single layer printed circuit board made in accordance with a method of the present disclosure;

FIG. 11 is a dual layer printed circuit board made in accordance with a method of the present disclosure; and

FIG. 12 is a multi-layer printed circuit board made in accordance with a method of the present disclosure.

### DETAILED DESCRIPTION

Before describing the present disclosure in detail, it is to be understood that the terminology used in the specification is for the purpose of describing particular embodiments and is not necessarily intended to be limiting. Although many methods, structures, and materials similar, modified, or equivalent to those described herein may be used in the practice of the present disclosure without undue experimentation, the preferred methods, structures, and materials are described herein. In describing and claiming the present disclosure, the following terminology will be used in accordance with the definitions set out below.

As used herein, the singular forms “a,” “an,” and “the” do not preclude plural referents, unless the content clearly dictates otherwise.

As used herein, the term “and/or” includes any and all combinations of one or more of the associated listed items.

As used herein, the term “about” when used in conjunction with a stated numerical value or range denotes somewhat more or somewhat less than the stated value or range, to within a range of ±10% of that stated.

This invention describes systems and apparatus for a wearable platform consisting of all, or some combination of, microfluidics layers, microneedle arrays, electrochemical transducers, and printed circuits on, within, and under the surface of ecologically friendly organic substrates, such as bacterial nanocellulose. Nanocellulose is a crystalline or semi-crystalline phase of cellulose in which at least one dimension is on the nanoscale. Microbial/bacterial nanocellulose is nanocellulose grown as a product of certain bacteria, such as Acetobacter xylinum, through ingestion of glucose (fermentation).

The organic substrate may serve multiple purposes, such as all or any combination of the following: a substrate for the PCB; a backing layer for a microneedle array that may or may not be embedded into the PCB substrate; a microfluidics layer; and the substrate for electrochemical sensors which may or may not be connected to the PCB.

The present disclosure discusses a system for a wearables platform comprising all or any combination of the following: a printed circuit board (PCB) on, within, and/or under the surface of ecologically-friendly organic substrate materials, such as bacterial nanocellulose; a microneedle array on one side of the substrate that adheres to the skin of a human or animal, in some embodiments connected to a microfluidics layer, in other embodiments, connected to a sensor; a microfluidics layer embedded into the said substrate; and a sensor, such as an electrochemical transducer, connected to the electrical circuitry located on the PCB, which in some embodiments may be connected to the microneedle array, and in other embodiments may be connected to a microfluidics layer.

The present disclosure further discusses methods for depositing conductive traces and pads for the later installation of electronic components, and conductive vias connecting conductive traces between two or more layers onto an organic substrate, such as nanocellulose. In one or more embodiments, the present disclosure contemplates that three different additive deposition methods may be utilized to achieve the end goal of forming a PCB on an organic material substrate: (1) aerosol deposition of conductive materials (metal particles such as silver, copper, carbon, etc., as well as liquid metals) and dielectric compounds; (2) direct printing of conductive and dielectric materials via inkjet and direct-write/extrusion printing; and (3) screen printing of conductive and dielectric inks/pastes.

In one or more embodiments of the present disclosure, the method for deposition does not use an electroless plating step. As used herein, the term “electroless” refers to a plating method conducted in solution and occurring without the use of external electrical power.

Liquid metals such as gallium indium eutectic, Galinstan, etc. are a class of non-toxic, self-healing, flexible alloys. In one or more embodiments, the present disclosure utilizes aerosol deposition of atomized liquid metal particles to deposit conductive traces onto an organic substrate such as bacterial nanocellulose. This process may but may not, include mixing liquid metal with an aliphatic alcohol such as ethanol so that the liquid metal particles may be small enough to pass through an aerosol spray nozzle. Liquid metal microparticles may be patterned onto substrates using lithographic tools such as stencils and masks. The aerosol spray pressure must be strong enough to produce sufficient kinetic energy to atomize the liquid metal particles, distorting them on impact and allowing them to merge together into definable patterns on a substrate, such as bacterial nanocellulose, with sufficient wettability. Aerosol deposition may also be used to deposit conductive traces using traditional metal compounds instead of liquid metal. These traditional metals include silver, copper, nickel, carbon, etc. and may be deposited via spraying onto the organic substrate. Aerosol deposition may also be used to deposit insulating layers onto the organic substrate, using the same methodology outlined above.

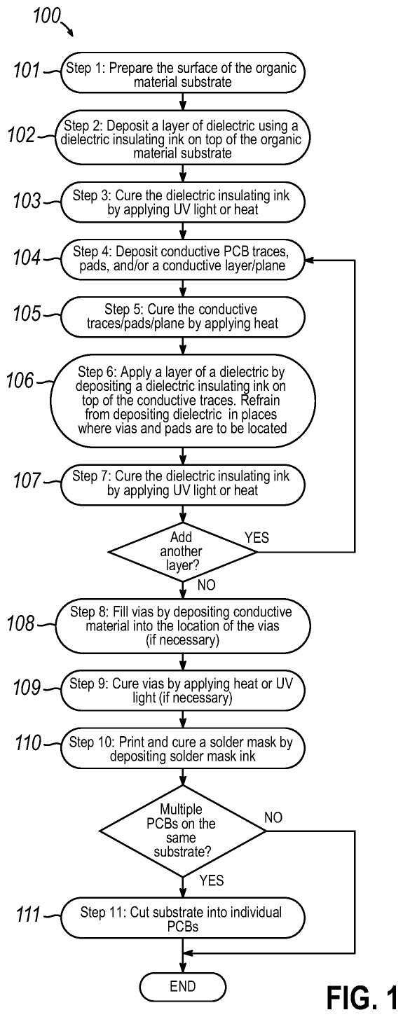

FIG. 1 shows a flowchart describing a method 100 for fabricating either single layer, dual layer, or multi-layer PCBs on an organic material substrate, using an additive deposition method such as extrusion/direct-write printing, inkjet printing, gravure printing, flexographic printing, electrohydrodynamic (EHD) printing, or laser-induced forward transfer (LIFT). In one or more embodiments, a first step 101 includes preparation of the surface of the organic material substrate, and in one or more embodiments, this step may be done by cleaning the surface of the substrate with a lint-free wipe using ethanol or isopropyl alcohol. In one or more embodiments, the organic material substrate may be selected from the group consisting of bacterial nanocellulose or microbial nanocellulose.

In one or more embodiments, a second step 102 may include the application of a layer of a dielectric material by an additive deposition method such as extrusion/direct-write printing, inkjet printing, gravure printing, flexographic printing, electrohydrodynamic (EHD) printing, or laser-induced forward transfer (LIFT) utilizing a dielectric insulating ink on the top of the organic material substrate. In one or more embodiments, the dielectric insulating ink may be selected from urethane, silicone, acrylic, or epoxy compounds and may be in water or solvent-based dispersion form. In one or more embodiments, the second step 102 may be considered to be an optional step, only necessary if adhesion of conductive materials, applied at a later step, to the organic material substrate may be difficult.

In one or more embodiments, a third step 103 may include heat treating the layer of the dielectric materials. In one or more embodiments, heat treating may include sintering and or curing of the layer of dielectric materials. In one or more embodiments, the step of heat-treating takes place utilizing UV light, such as an LED light, drying over time in ambient air, or placing the substrate into a temperature-controlled oven. In one or more embodiments, if the step of heat-treating utilizes UV light, the light should be between 250-450 nm. In one or more embodiments, if heat-treating is done by drying over time in ambient air, the ambient air should be in the temperature range of between 60° F. and 85° F. for between about 10 minutes to as long as 48 hours. In one or more embodiments, if heat-treating is done by placing the substrate into a temperature-controlled oven, then the oven should have a temperature of between 120° F. and 390° F. for between about 10 minutes to as long as 48 hours. In one or more embodiments, the third step 103 may be considered to be an optional step, only necessary if optional step 102 is performed.

In one or more embodiments, a fourth step 104 may include the application of conductive PCB traces, and/or pads, and/or conductive layers/planes by an additive deposition method such as extrusion/direct-write printing, inkjet printing, gravure printing, flexographic printing, electrohydrodynamic (EHD) printing, or laser-induced forward transfer (LIFT) utilizing conductive compounds such that the conductive compounds may be selectively deposited on the substrate. In one or more embodiments, the conductive compounds may be selected from the group consisting of metal particles selected from the group consisting of gold, silver, platinum, copper, nickel, and carbon. In one or more embodiments, the conductive material may be two-dimensional inorganic compounds, including transition metal carbides, carbonitrides, and nitrides, also known as MXenes. In one or more embodiments, the conductive compound may be in the form of a liquid metal composition. In one or more embodiments, the liquid metal in the liquid metal composition may be selected from the group consisting of eutectic gallium-indium and Galinstan. In one or more embodiments, the PCB traces, and/or pads, and/or conductive layers/planes may only be placed where needed on the substrate, and that in most instances, the application of the conductive material may not take place over the entirety of the substrate. In one or more embodiments, if the method 100 fabricates a dual layer, or multi-layer PCBs, an entire layer of the substrate may be covered in conductive material to serve as a ground or power plane.

In one or more embodiments, a fifth step 105 may include heat-treating the applied conductive materials deposited in step 104 utilizing heat or UV light. In one or more embodiments, heat treating may include sintering and or curing of the applied conductive materials. This step may be needed to activate the conductive compounds laid down in step 104 above. In one or more embodiments, if eutectic gallium-indium liquid metal is used as the conductive compounds, then the fifth step 105 may not be necessary. However, the fifth step 105 may be necessary if other conductive compounds are utilized. If performed, heat-treating may be performed using an oven, hot plate, heat press, laminator, or similar heat-producing equipment. This step helps ensure adhesion of the conductive material to the substrate or previous dielectric layer/plane. Most importantly, it removes protective compounds from the conductive material itself, enabling direct physical contact between conductive particles so as to establish a dense, conductive network. In one or more embodiments, heat-treating takes place at temperatures of about 285° F. and above for between about 5 minutes and about 20 minutes. In one or more embodiments, heat-treating at higher temperatures (up to 410° F.) and longer times (30 minutes or more) may provide better adhesion and conductivity.

In one or more embodiments, a sixth step 106 may include the application of a layer of dielectric material by an additive deposition method such as extrusion/direct-write printing, inkjet printing, gravure printing, flexographic printing, electrohydrodynamic (EHD) printing, or laser-induced forward transfer (LIFT) utilizing a dielectric insulating ink on a portion of the heat-treated conductive material laid down in a previous step. In yet other embodiments, the dielectric insulating ink may also be applied on non-conductive portions of the substrate to protect the conductive material laid down in a previous step from being exposed to damage and/or from shorting out. If a conductive pad has been previously laid down, it is important to note that the dielectric material would not be laid down on the pad because the pads will be utilized to place electronic components on the printed circuit board. In one or more embodiments, the dielectric insulating ink may be selected from urethane, silicone, acrylic, or epoxy compounds and may be in water or solvent-based dispersion form. In one or more embodiments, the application of a layer of dielectric material utilizes a PCB layout file that specifies the pattern in which the dielectric layer or plane may be laid, and, if a dual layered or multi-layered PCB is being made, where any vias may be found. Accordingly, in the location of vias, the dielectric insulating ink may not be applied. So, by not applying the dielectric material over the entirety of the layer of the conductive material, the sixth step also entails the creation of the vias on the substrate.

In one or more embodiments, if vias are to be utilized on the formed PCBS, they may also be created by drilling holes into the substrate, either mechanically, or with a laser. In the instances in which the vias are created this way, the vias may be created prior to the deposition of any dielectric or conductive material onto the substrate. In one or more embodiments, if the vias are drilled prior to the laying down of conductive material, then during step 104 as discussed above, the vias are filled with conductive material during deposition of the conductive material to form traces and/or pads. If the vias are filled with conductive material at the same time the conductive traces and/or pads are created, then the vias filled with conductive material would be heat treated during the fifth step 105 as discussed above.

In one or more embodiments, a seventh step 107 may include heat-treating the layer of dielectric material applied in the previous step. In one or more embodiments, heat treating may include sintering and or curing of the layer of dielectric material. In one or more embodiments, the step of heat-treating takes place utilizing UV light, such as an LED light, drying over time in ambient air, or placing the substrate into a temperature-controlled oven. In one or more embodiments, if the step of heat-treating utilizes UV light, the light should be between 250-450 nm. In one or more embodiments, if heat-treating is done by drying over time in ambient air, the ambient air should be in the temperature range of between 60° F. and 85° F. for between about 10 minutes to as long as 48 hours. In one or more embodiments, if heat-treating is done by placing the substrate into a temperature-controlled oven, then the oven should have a temperature of between 120° F. and 390° F. for between about 10 minutes to as long as 48 hours.

After the seventh step 107, if a dual layer or multi-layer PCB is desired, then steps 104-107 may be repeated for as many times as there may be layers desired.

Once the desired number of layers has been created, the method of the present disclosure may move forward to an eighth step 108 which may include the filling in of vias with conductive material by an additive deposition method such as extrusion/direct-write printing, inkjet printing, gravure printing, flexographic printing, electrohydrodynamic (EHD) printing, or laser-induced forward transfer (LIFT) of the material in the specific location of the vias. In one or more embodiments, the conductive material may be selected from the group consisting of liquid metal, conductive inks, conductive pastes, conductive resins, and conductive epoxies containing silver, silver coated copper, copper, and other conductive material.

In one or more embodiments, a ninth step 109 may include heat-treating of the applied conductive ink utilizing heat or UV light. In one or more embodiments, heat-treating includes sintering or curing of the applied conductive ink. In one or more embodiments, if eutectic gallium-indium liquid metal is used as the conductive compounds, then the ninth step 109 may not be necessary. However, the ninth step 109 may be necessary if other conductive compounds are utilized. If performed, heat-treating may be performed using an oven, hot plate, heat press, laminator, or similar heat-producing equipment. This step helps ensure adhesion of the conductive material to the substrate or previous dielectric layer/plane. Most importantly, it removes protective compounds from the conductive material itself, enabling direct physical contact between conductive particles so as to establish a dense, conductive network. In one or more embodiments, heat-treating usually takes place at temperatures of about 285° F. and above for between about 5 minutes and about 20 minutes. In one or more embodiments, heat-treating at higher temperatures (up to 410° F.) and longer times (30 minutes or more) may provide better adhesion and conductivity.

In one or more embodiments, step 104 may include only the deposition of conductive material to form the PCB traces. In such embodiments, after step 109 there could optionally be additional steps not shown in FIG. 1, which may include the creation of PCB pads by an additive deposition method such as extrusion/direct-write printing, inkjet printing, gravure printing, flexographic printing, electrohydrodynamic (EHD) printing, or laser-induced forward transfer (LIFT) utilizing a conductive material. Regardless of what step in the process the PCB pads are created, PCB pads may be needed for the mounting of electronic components. Optionally, the PCB pads may be made thicker by using multiple passes, or thicker depositions, of the conductive material. In one or more embodiments, the pads may most commonly be created using copper or silver. However, in other embodiments, other conductive compounds may be used to form pads, so long as the conductive compound may be amenable to soldering, epoxy adhesive, or other methods of component adhesion.

If the PCB pads are created in an additional step, then the method 100 may also include another additional step which may include heat-treating the previously deposited conductive material for the PCB pads by applying heat. In one or more embodiments, heat-treating includes sintering or curing of the conductive material. The time that may be needed to heat-treat this layer may be longer due to the increased thickness of the PCB pads, and, accordingly, any additional step of heat-treating the conductive material used for the PCB pads needs to take place for a longer time period as compared a heat-treating step that was only treating conductive traces.

In one or more embodiments, a tenth step 110 may include the application of a solder mask by an additive deposition method such as extrusion/direct-write printing, inkjet printing, gravure printing, flexographic printing, electrohydrodynamic (EHD) printing, or laser-induced forward transfer (LIFT) utilizing a solder mask ink or encapsulant. In one or more embodiments, a solder mask may be a thin layer of a polymer, most commonly epoxy liquid. In one or more embodiments, a solder mask may also consist of other polymer encapsulants such as urethanes, acrylics, or silicone. Once applied, the solder mask may need to be heat-treated, either thermally or via UV light. The solder mask protects the traces, pads, and vias from oxidation while also preventing solder bridges from being formed between adjacent PCB pads. In one or more embodiments, this step may be optional as the top layer of dielectric material may serve the same purpose as the laying of a solder mask. The end goal of the PCB may determine if the solder mask may be needed.

In one or more embodiments, the method 100 may include an optional eleventh step 111, if multiple PCBs were prepared on the same substrate, then the substrate should be cut to form the individual PCBs.

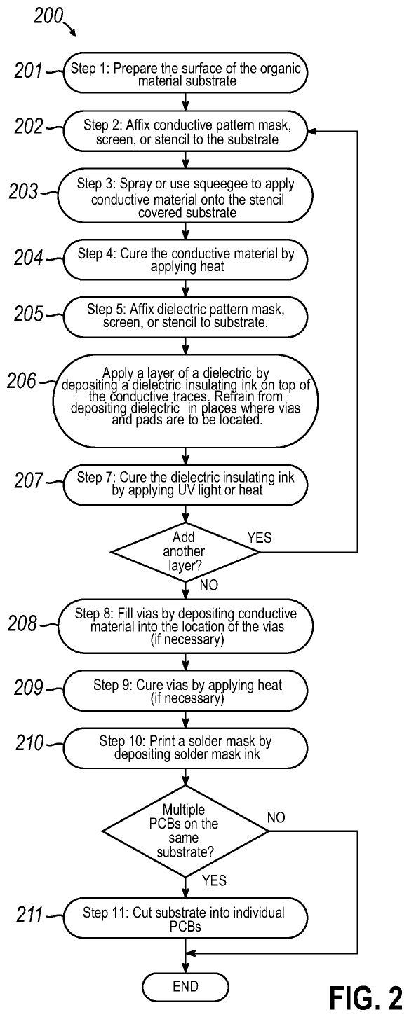

FIG. 2 shows a flowchart describing a method 200 for fabricating either single layer, dual layer, or multi-layer PCBs on an organic material substrate, using aerosol deposition or screen-printing as the additive deposition method. In one or more embodiments, a first step 201 may include preparation of the surface of the organic material substrate, and in one or more embodiments, this step may be done by cleaning the surface of the substrate with a lint-free wipe using ethanol or isopropyl alcohol. In one or more embodiments, the organic material substrate may be selected from the group consisting of bacterial nanocellulose or microbial nanocellulose.

In one or more embodiments, a second step 202 may include affixing a conductive pattern mask, screen mesh, or stencil to the organic material substrate. The conductive pattern mask, screen mesh, or stencil may provide the printing guide or pathway for the aerosol deposition or screen printing that may take place in the steps that follow.

In one or more embodiments, a third step 203 may include the application of conductive PCB traces, and/or pads, and/or conductive layers/planes utilizing aerosol deposition or screen-printing over the conductive pattern mask or stencil utilizing conductive compounds such that the conductive compounds may be selectively deposited on the substrate. In one or more embodiments, aerosol deposition would utilize a spraying method to apply the conductive compound, and screen-printing would utilize a squeegee or a blade to apply the conductive compound. In one or more embodiments, the conductive compounds may be selected from the group consisting of metal particles selected from the group consisting of gold, silver, platinum, copper, nickel, and carbon. In one or more embodiments, the conductive material may be two-dimensional inorganic compounds, including transition metal carbides, carbonitrides, and nitrides (MXenes). In one or more embodiments the conductive compound may be in the form of a liquid metal composition. In one or more embodiments, the liquid metal in the liquid metal composition may be selected from the group consisting of eutectic gallium-indium and Galinstan. In one or more embodiments, the conductive PCB traces, and/or pads, and/or conductive layers/planes may only be placed where needed on the substrate, as defined by the conductive pattern mask or stencil, and that in most instances, the application of the conductive material may not take place over the entirety of the substrate.

In one or more embodiments, a fourth step 204 may include heat-treating the applied conductive material utilizing heat or UV light. In one or more embodiments, heat-treating includes sintering and curing of the applied conductive material. This step may be needed to activate the conductive compounds laid down in step 203 above. In one or more embodiments, if eutectic gallium-indium liquid metal is used as the conductive compounds, then the fourth step 204 may not be necessary. However, the fourth step 204 may be necessary if any other conductive compound is utilized. If performed, heat-treating may be performed using an oven, hot plate, heat press, laminator, or similar heat-producing equipment. This step helps ensure adhesion of the conductive material to the substrate or previous dielectric layer/plane. Most importantly, it removes protective compounds from the conductive material itself, enabling direct physical contact between conductive particles so as to establish a dense, conductive network. In one or more embodiments, heat-treating usually takes place at temperatures of about 285° F. and above for between about 5 minutes and about 20 minutes. In one or more embodiments, heat-treating at higher temperatures (up to 410° F.) and longer times (30 minutes or more) may provide better adhesion and conductivity.

In one or more embodiments, a fifth step 205 may include affixing a dielectric pattern mask, screen mesh, or stencil to the organic material substrate. The dielectric pattern mask, screen mesh, or stencil may provide the printing guide or pathway for the aerosol deposition or screen printing that may take place in the steps that follow.

In one or more embodiments, a sixth step 206 may include the application of a layer of dielectric material utilizing aerosol deposition or screen-printing utilizing a dielectric insulating ink on top of the conductive material laid down in a previous step. During this step, if a multi-layered PCB is desired by the method 200, then care should be taken such that the dielectric material may not be deposited in places where vias may be placed. The use of the dielectric pattern mask, screen mesh, or stencil, which covers up positions wherein vias may be needed, should assist in this regard. Regardless of the type of PCB being made by the method 200, care should also be taken such that the dielectric material may not be deposited in places where the PCB pads have been placed or may be placed if the PCB pads were not placed in step 203 as discussed in more detail below. In one or more embodiments, the dielectric insulating ink may be selected from urethane, silicone, acrylic, or epoxy compounds and may be in water or solvent-based dispersion form. So, by not applying the dielectric material over the entirety of the layer of the conductive material, the fifth step also entails the creation of the vias on the substrate. In one or more embodiments, if vias are to be utilized on the formed PCBs, they may also be created by drilling holes into the substrate, either mechanically, or with a laser. In the instances in which the vias are created this way, the vias may be created prior to the deposition of any dielectric or conductive material onto the substrate. In one or more embodiments, if the vias are drilled prior to the laying down of conductive material, then during step 203 as discussed above, the vias are filled with conductive material during deposition of the conductive material to form traces and/or pads. If the vias are filled with conductive material at the same time the conductive traces and/or pads are created, then the vias filled with conductive material would be heat treated during the fifth step 204 as discussed above.

In one or more embodiments, a seventh step 207 may include heat-treating the layer of dielectric material applied in a previous step. In one or more embodiments, heat-treating may include sintering or curing of the layer of dielectric material. In one or more embodiments, the step of heat-treating takes place utilizing UV light, such as an LED light, drying over time in ambient air, or placing the substrate into a temperature-controlled oven. In one or more embodiments, if the step of heat-treating utilizes UV light, the light should be between 250-450 nm. In one or more embodiments, if heat-treating is done by drying over time in ambient air, the ambient air should be in the temperature range of between 60 ° F. and 85° F. for between about 10 minutes to as long as 48 hours. In one or more embodiments, if heat-treating is done by placing the substrate into a temperature-controlled oven, then the oven should have a temperature of between 120° F. and 390° F. for between about 10 minutes to as long as 48 hours.

After the seventh step 207, if a dual layer or multi-layer PCB is desired, then steps 202-206 may be repeated for as many times as there may be layers desired.

In one or more embodiments, once the desired number of layers has been created, the method 200 of the present disclosure may move forward to the eighth step 208 which may include the filling in of vias with conductive material by aerosol deposition or screen-printing of the material in the specific location of the vias. In one or more embodiments, vias may also be filled by selective deposition of conductive material using manual and automated dispensing equipment. In one or more embodiments, the conductive material may be selected from the group consisting of liquid metal, conductive inks, conductive pastes, conductive resins, and conductive epoxies containing silver, silver coated copper, copper, and other conductive material.

In one or more embodiments, a ninth step 209 may include heat-treating of the applied conductive ink utilizing heat or UV light. In one or more embodiments, heat-treating may include sintering or curing of the applied conductive ink. In one or more embodiments, if eutectic gallium-indium liquid metal is used as the conductive compounds, then the ninth step 209 may not be necessary. However, the ninth step 209 may be necessary if any other conductive compound is utilized. If performed, heat-treating may be performed using an oven, hot plate, heat press, laminator, or similar heat-producing equipment. This step helps ensure adhesion of the conductive material to the substrate or previous dielectric layer/plane. Most importantly, it removes protective compounds from the conductive material itself, enabling direct physical contact between conductive particles so as to establish a dense, conductive network. In one or more embodiments, heat-treating usually takes place at temperatures of about 285° F. and above for between about 5 minutes and about 20 minutes. In one or more embodiments, heat-treating at higher temperatures (up to 410° F.) and longer times (30 minutes or more) may provide better adhesion and conductivity.

In one or more embodiments, step 203 may include only the deposition of conductive material to form the PCB traces. In such embodiments, after step 209 there could optionally be additional steps not shown in FIG. 2, which may include the creation of PCB pads by aerosol deposition or screen-printing of a conductive material. In one or more embodiments, a pattern mask, screen mesh, or stencil may be utilized to create the PCB pads. Regardless of what step in the process the PCB pads are created, PCB pads may be needed for the mounting of electronic components. Optionally, the PCB pads may be made thicker by using multiple passes, or thicker depositions, of the conductive material. In one or more embodiments, the pads may most commonly be created using copper or silver. However, in other embodiments, other conductive compounds may be used to form pads, so long as the conductive compound may be amenable to soldering, epoxy adhesives, or other methods of component adhesion.

If the PCB pads are created in an additional step, then the method 100 may also include another additional step which may include heat-treating the previously deposited conductive material for the PCB pads by applying heat or UV light. In one or more embodiments, heat-treating may include sintering or curing of the deposited conductive material. The time that may be needed to heat-treat this layer may be longer due to the increased thickness of the PCB pads, and, accordingly, the step of heat-treating the conductive material used for the PCB pads needs to take place for a longer time period as compared a heat-treatment step that was only treating conductive traces.

In one or more embodiments, a tenth step 210 may include the application of a solder mask by aerosol deposition or screen-printing utilizing a solder mask ink or encapsulant. In one or more embodiments, with method 200, the solder mask may also be applied using inkjet printing or other additive deposition methods previously listed. In one or more embodiments, a solder mask may be a thin layer of a polymer, most commonly epoxy liquid. In one or more embodiments, a solder mask may also consist of other polymer encapsulants such as urethanes, acrylics, or silicone. Once applied, the solder mask may need to be heat-treated, either thermally or via UV light. The solder mask protects the traces, pads, and vias from oxidation while also preventing solder bridges from being formed between adjacent PCB pads. In one or more embodiments, this step may be optional, as the top layer of dielectric material may serve the same purpose as the laying of a solder mask. The end goal of the PCB may determine if the solder mask may be needed.

In one or more embodiments, the method 100 may include an optional eleventh step 211 if multiple PCBs were prepared on the same substrate, then the substrate should be cut to form the individual PCBs.

The porosity and hydrophilicity of bacterial and microbial nanocellulose also allow for the absorption of compounds and reagents, including conductive and dielectric inks and pastes. By using the additive deposition methods disclosed above for depositing conductive traces and dielectric layers onto or into the organic substrates, the organic substrates may be imbued with conductive and insulative properties.

In one or more embodiments, wherein the method of additive deposition utilizes screen printing, the conductive traces, and dielectric layers may be deposited onto the organic substrate via manual, semi-automatic, or automatic screen printing.

The present disclosure also contemplates the creation of vias in PCBs made on the organic material substrates utilized above. Vias may be utilized to connect the various layers of dual and/or multi-layers PCBs. In one embodiment, relying on the porosity and hydrophilicity of the organic substrate, a conductive material may be deposited through any of the additive deposition methods discussed above onto a location on the organic substrate where a via may be desired. In one or more embodiments, vias may also be created by depositing the conductive material until it penetrates to a depth equal to or greater than one-half the thickness of the organic substrate. In one or more embodiments, the conductive material may be selected from the group consisting of metal particles selected from the group consisting of gold, silver, platinum, copper, nickel, and carbon. In one or more embodiments the conductive material may be in the form of a liquid metal composition. In one or more embodiments, the liquid metal in the liquid metal composition may be selected from the group consisting of eutectic gallium-indium and Galinstan.

This step may then be repeated on the other side of the organic substrate in the location corresponding to the via started on the first side of the organic substrate. In this second step, the deposition of the conductive material may be continued until its absorption to the remaining depth of the non-conductive portion of the via to ensure the electrical connection, hence creating a fully conductive via. This method may be suitable only for creating vias in a dual-layer printed circuit but not in a multi-layer printed circuit. Multi-layer boards have a layer of dielectric in between each layer, so simply saturating the organic substrate with a conductive material may not create a via because the dielectric layer may be blocking it.

In another embodiment, holes may be drilled in the organic substrate using a mechanical or laser drilling method, such as laser ablation. Various lasers may be used, including but not limited to CO2, fiber, UV, and Nd-YAG. Once drilled, the surface of the created hole may be plated with conductive material, such as liquid metal, conductive inks, conductive pastes, conductive resins, and conductive epoxies containing silver, silver coated copper, copper, or other conductive materials.

In another embodiment, if the PCB is a multi-layered PCB, an additive process may be used in which vias may be created by not printing the dielectric materials in specific places. At the end of the printing process, the vias may be filled with conductive material and heat-treated. The layers may be held together by the inner dielectric material.

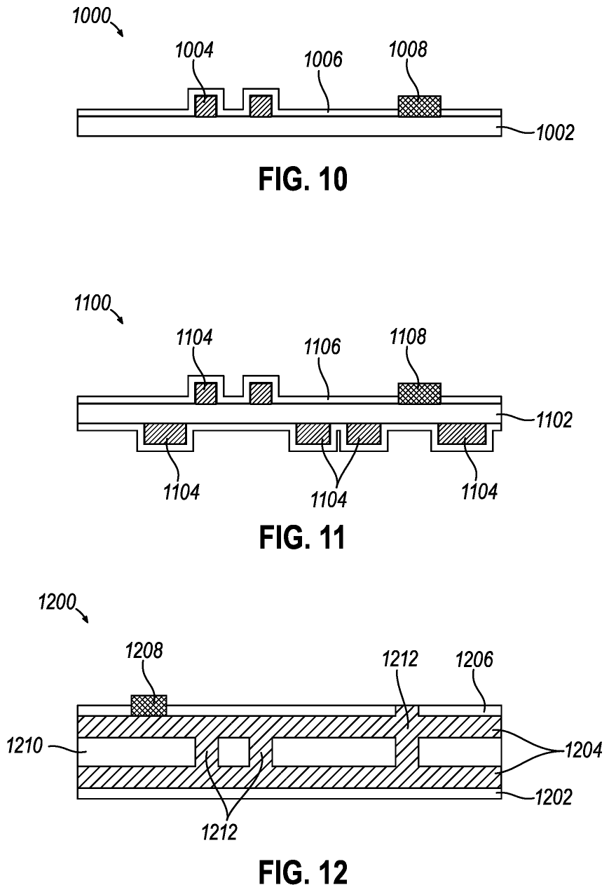

FIG. 10 shows a single layer board 1000 made in accordance with either method 100 or 200 as discussed above. As can be seen, the single layer board 1000 may include an organic substrate 1002 and conductive traces 1004 as discussed in methods 100 and 200 above. The single layer board 1000 may also include a protective upper layer 1006. This protective layer 1006 may 1006 may either be a dielectric layer, or a solder mask layer as discussed in methods 100 and 200 above. The single layer board 1000 may also include a conductive PCB pad 1008 as discussed in methods 100 and 200 above.

FIG. 11 shows a dual layer board 1100 made in accordance with either method 100 or 200 as discussed above. As can be seen, the dual layer board 1100 may include an organic substrate 1102 and conductive traces 1104 as discussed in methods 100 and 200 above. The dual layer board 1100 may also include a protective upper layer 1106. This protective layer 1106 may 1106 may either be a dielectric layer, or a solder mask layer as discussed above in methods 100 and 200 above. The dual layer board 1100 may also include a conductive PCB pad 1108 as discussed in methods 100 and 200 above. Although not shown, it may also be contemplated that the dual layer board 1100 may include vias, also as discussed above in methods 100 and 200.

FIG. 12 shows a multi-layer board 1200 made in accordance with either method 100 or 200 as discussed above. As can be seen, the multi-layer board 1200 may include an organic substrate 1202 and conductive layers 1204 as discussed above in methods 100 and 200. The multi-layer board 1200 may also include a protective upper layer 1206. This protective layer 1206 may 1206 may either be a dielectric layer, or a solder mask layer as discussed above in methods 100 and 200. The multi-layer board 1200 may also include a conductive PCB pad 1208 as discussed above in methods 100 and 200. As this is a multi-layer board, there may also be layers of dielectric material 1210, separate from the protective layer 1206, as discussed above in methods 100 and 200. The multi-layer board 1200 also shows optional vias 1212 as discussed above in methods 100 and 200.

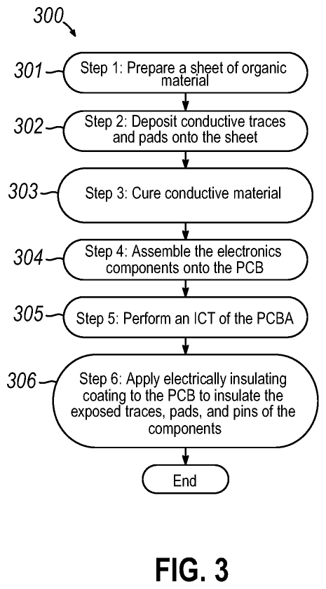

Once the boards as shown in FIGS. 10-12 have been formed, they may be utilized as a base on which to mount electrical, electromechanical, or mechanical components. For a single-layer printed circuit, any of the above discussed methods may be used to deposit traces and pads on one surface of the organic substrate for the later installation of electronic components. FIG. 3 showcases a method 300 for creating a single layer printed circuit board. Once the board has been created, as shown in steps 301-303 (and discussed in more detail in FIGS. 1 and 2), step 304 may include the assembly of the electronic components onto the board. Step 305 may include the performance of an in-circuit test of the newly formed printed circuit board assembly (PCBA). Step 306 may include the application of an electrically insulating coating to the PCBA to insulate the exposed traces, pads, and pins of the components. In one or more embodiments, the electrically insulating coating may be selected from the group consisting of epoxies, urethanes, acrylics, or silicones.

For a dual-layer printed circuit, any of the above discussed methods may be used to deposit traces and pads on both surfaces (top/bottom) of the organic substrate, followed by the creation of vias using any of the methods discussed above for via creation. Similar to a single layer board, once the board has been created, the vias may be created, and the electronic components may then be assembled onto the board. An in-circuit test may then be performed on the newly formed PCBA, and finally, an electrically insulating coating may be applied to the PCBA to insulate the exposed traces, pads, and pins of the components. In one or more embodiments, the electrically insulating coating may be selected from the group consisting of epoxies, urethanes, acrylics, or silicones.

For multi-layered printed circuits, where the number of layers equals more than two, any of the above discussed methods may be used to deposit traces and pads on the various layers. As discussed above, an additive process may be used in which vias may be created by not printing the dielectric materials in specific places. At the end of the printing process, the vias may be filled with conductive ink and heat-treated. The layers may be held together by the inner dielectric material. An in-circuit test may then be performed on the newly formed PCBA, and finally, an electrically insulating coating may be applied to the PCBA to insulate the exposed traces, pads, and pins of the components. In one or more embodiments, the electrically insulating coating may be selected from the group consisting of epoxies, urethanes, acrylics, or silicones.

As discussed above, the single, dual, and multi-layered PCBs may all include a layer of electrically insulating coating. The layer of electrically insulating coating may dry via ambient temperature, by using a temperature-controlled oven or chamber with low humidity, creating an airflow to evacuate vapor and hence accelerate the process of drying, or by subjecting to UV light for heat-treating purposes. In one or more embodiments, if the step of heat-treating utilizes UV light, the light should be between 250-450 nm. In one or more embodiments, if drying over time in ambient air, the ambient air should be in the temperature range of between 60° F. and 85° F. for between about 10 minutes to as long as 48 hours. In one or more embodiments, if placing the substrate into a temperature-controlled oven, then the oven may have a temperature of between 120° F. and 390° F. for between about 10 minutes to as long as 48 hours

In an embodiment wherein dual-layered PCBs are created, but multi-layered PCBs are desired, they may be stacked up in a designated order. The next step of the process may then be the alignment of the dual-layer printed circuits to create a multi-layered PCB. Once the dual-layer printed circuits are aligned, they may need to be secured together. This may be done using one or a combination of the following methods: adhesive placed in between the dual-layer printed circuits or drilling special vias in designated locations that may be consequently filled with an adhesive, hence securing the entire stack of the dual-layer printed circuits together. The next step of the process may then be cutting the extra material in the organic substrate to the desired size around the outer perimeter of the resulting multi-layer printed circuit and binding together the edges of each dual-layer printed circuit using thermal fusing, pressure fusing, or applying an adhesive. Next, vias may be formed as discussed above when dealing with a multi-layered PCB.

The present disclosure also contemplates the fabrication of microneedle arrays utilizing an organic material substrate, which may be selected from the group consisting of bacterial nanocellulose or microbial nanocellulose. The organic material substrate may be utilized as the backing layer in which drugs, reagents, and other therapeutics may or may not be deposited to form a closed-loop monitoring and/or drug delivery system. Microneedles penetrate the skin at a shallow enough depth to not cause pain yet to create micron-sized channels in the skin. This may be achieved by either penetrating the outer layer of skin (the “stratum corneum”) and reaching the epidermis with short needles, typically between 0.25 millimeters and 0.80 millimeters, or by penetrating the epidermis and reaching the dermis with longer needles up to 2-3 millimeters. Reaching the epidermis or dermis may allow for the identification and monitoring of analytes and biomarkers that may be present in bodily fluids such as sweat or interstitial fluid, as well as the delivery of drugs coated on the needle surface, within the needles themselves, or in the backing layer of the microneedle patch.

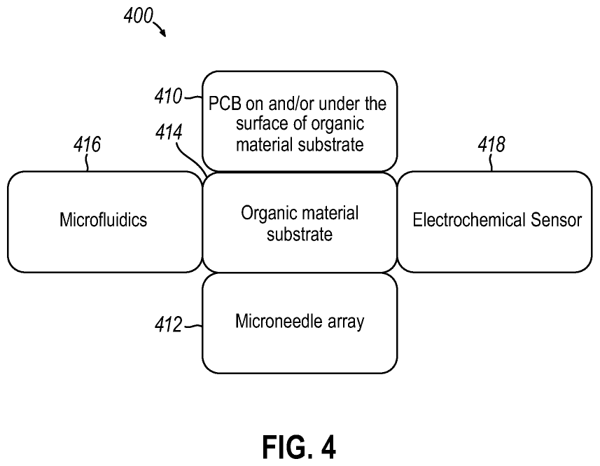

The microneedle arrays may then be combined with the bacterial nanocellulose PCBs discussed above to create wearable sensor platforms, such as the wearable platforms 400, 600, 700, 800, and 900 respectively shown in FIGS. 4, and 6-9. In one or more embodiments, the sensing platforms may include a bacterial nanocellulose printed circuit board 410, a microneedle array 412, and a bacterial nanocellulose backing layer 414 in between the PCB and the array.

In one or more embodiments, dispersed bacterial nanocellulose in an aqueous solution may be used as the backing layer for a microneedle array. In such an embodiment, an aqueous solution containing dispersed bacterial nanocellulose and other natural polymers such as hyaluronic acid and carboxymethyl cellulose, may be combined to form a dissolvable microneedle array. In an optional step, this solution may then be subjected to centrifugal forces and the solution may then dried such that the dispersed nanocellulose forms a mechanically strong backing to support the microneedles. In one or more embodiments, the microneedles may also be formed of the same aqueous solution containing dispersed bacterial nanocellulose and other natural polymers such as hyaluronic acid and carboxymethyl cellulose that forms the backing layer. In yet other embodiments, the microneedles may be formed of primarily natural polymers. In other embodiments, the microneedles may be solid or hollow and may be made from silicon, stainless steel, titanium, gold, and/or combinations thereof.

With the bacterial nanocellulose backing layer serving as an additional reservoir to load drugs, reagents, or other therapeutics, microneedle arrays of the present disclosure may deliver larger amounts of treatment via transdermal delivery. Drugs may be added to the bacterial nanocellulose backing by methods such as soaking the backing in solution, drop casting, or direct injection. Once the nanocellulose pores have been filled, release of the drug may be controlled by varying concentration levels, the utilization of dissolvable blockers/barriers, electrochemical stimulation, and other mechanisms.

To further enhance biosensing capabilities, and better integrate the microneedle array with the nanocellulose PCB, the conductive microneedle arrays may be fabricated by utilizing bacterial nanocellulose combined with conducting polymers such as polyaniline, polypyrrole, and poly(3,4-ethylenedioxythiophene) polystyrene sulfonate, or other conductive compounds such as transition metal carbides, nitrides, or carbonitrides (MXenes), silver nanoparticles, silver nanowires, or carbon nanotubes. To do this, the conductive polymers or compounds may be loaded into the nanocellulose utilizing sputtering, spin coating, electrodeposition, drop casting, aerosol deposition, or soaking in a conductive solution such that the conductive material may be absorbed into the pores of the nanocellulose, imbuing it with conductivity. In other embodiments, the microneedles and/or nanocellulose substrate may be sprayed with an aerosol-based conductive coating, such as silver, silver copper, or nickel such that the sprayed surfaces may be imbued with a thin conductive coating. Multiple passes/spraying may be applied to increase the thickness or conductivity as may be needed.

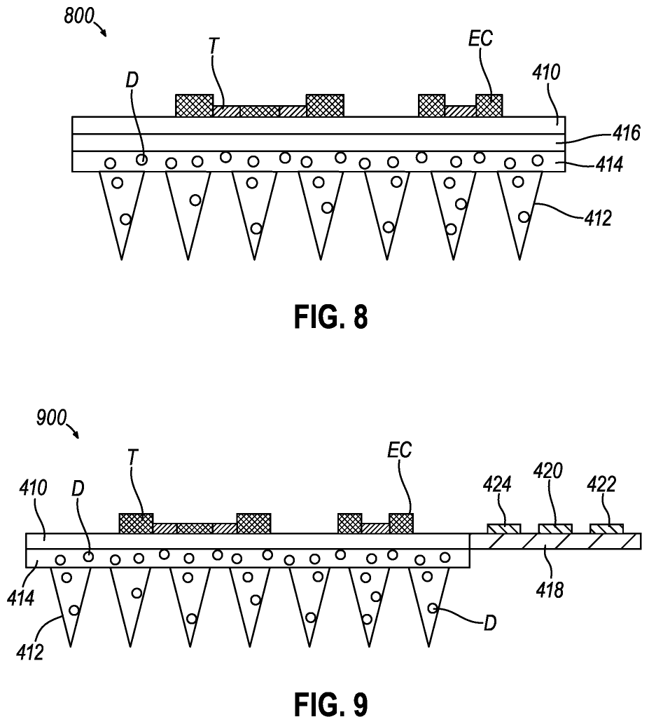

In one or more embodiments, such as shown in FIGS. 4 and 8, the sensing platform may also include a bacterial nanocellulose based microfluidic channel layer 416. The bacterial nanocellulose based microfluidic channel layer may be integrated as a separate layer, between the bacterial nanocellulose backing layer and the bacterial nanocellulose PCB substrate. In other embodiments, instead of having its own layer, the microfluidic channels may share the same substrate layers as the bacterial nanocellulose backing layer and the bacterial nanocellulose PCB substrate. In one or more embodiments, the microfluidic channels may be fabricated from laser ablation and/or selective filling of the pores such that analytes, biomarkers, and/or other substances of interest may travel selectively along a horizontal or vertical route to a sensing mechanism.

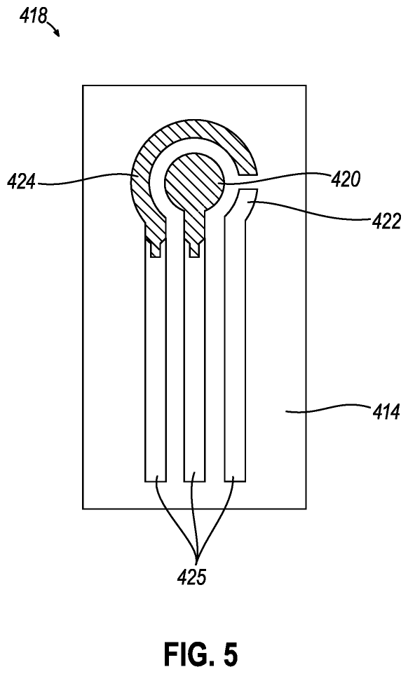

The sensing platforms of the present invention may selectively identify analytes and biomarkers via bodily fluids-based epidermal sensing. Bacterial nanocellulose may serve as the substrate for the electrochemical sensors, or simply the adhesive layer, allowing it to be attached directly to human or animal skin, or attached to other portions of the nanocellulose based sensing system, such as a PCB. The electrochemical sensors, such as electrochemical sensor 418 as shown in FIG. 4, may have a variety of geometries and patterns, such as, as shown in FIG. 5, a working electrode 420, a reference electrode 422, and a counter electrode 424 each having leads 425 being placed on a nanocellulose substrate 414 of the present invention. These electrodes may be functionalized by depositing precursors, enzymes, or other reagents to allow for the identification and measurement of analytes of interest.

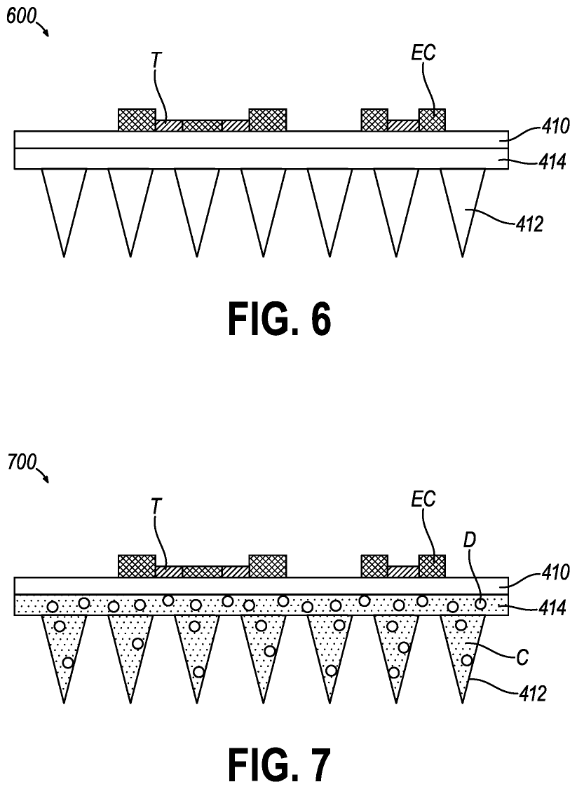

FIG. 6 is a bacterial nanocellulose platform 600 with a PCB 410, microneedle array 412, and an organic material substrate 414. Also shown in FIG. 6 are traces T and electronic components EC on the PCB 410.

FIG. 7 is a bacterial nanocellulose platform 700 with a PCB 410, a conductive microneedle array 412, and a conductive organic material substrate 414. FIG. 7 shows an embodiment wherein the conductive microneedle array 412 and the conductive organic material substrate 414 may be loaded with drugs D along with conductive particle and flakes C. Also shown in FIG. 7 are traces T and electronic components EC on PCB 410.

FIG. 8 is a bacterial nanocellulose platform 800 with a PCB 410, a microneedle array 412, an organic material substrate 414 and a microfluidics layer 416. FIG. 8 shows an embodiment wherein the microneedle array 412 and the microfluidics layer 416 may be loaded with drugs D. Also shown in FIG. 8 are traces T and electronic components EC on PCB 410.

FIG. 9 is a bacterial nanocellulose platform 900 with a PCB 410, a microneedle array 412, an organic material substrate 412, and an electrochemical sensor 418. FIG. 9 shows an embodiment wherein the microneedle array 412 and the microfluidics layer 416 may be loaded with drugs D. Also shown in FIG. 8 are traces T and electronic components EC on PCB 410 and a working electrode 420, a reference electrode 422, and a counter electrode 424 on the electrochemical sensor 418.

In various embodiments disclosed herein, a single component may be replaced by multiple components and multiple components may be replaced by a single component to perform a given function or functions. Except where such substitution would not be operative, such substitution is within the intended scope of the embodiments.

The foregoing description of embodiments and examples has been presented for purposes of illustration and description. It is not intended to be exhaustive or limiting to the forms described. Numerous modifications are possible in light of the above teachings. Some of those modifications have been discussed, and others will be understood by those skilled in the art. The embodiments were chosen and described in order to best illustrate principles of various embodiments as are suited to particular uses contemplated. The scope is, of course, not limited to the examples set forth herein, but can be employed in any number of applications and equivalent devices by those of ordinary skill in the art. Rather it is hereby intended the scope of the invention to be defined by the claims appended hereto.

1. A method for fabricating a printed circuit board, comprising the steps of:
a. providing an organic material substrate;
b. depositing conductive traces on the organic material substrate through an additive deposition process;
c. heat-treating the conductive traces to create electrically conductive pathways;
d. depositing dielectric material through the additive deposition process over a portion of the electrically conductive pathways to create a dielectric material containing area and a non-dielectric material containing area;
e. heat-treating the dielectric material containing area.

2. The method of claim 1, wherein the organic material substrate is selected from bacterial nanocellulose or microbial nanocellulose.

3. The method of claim 1, further comprising a step of preparing the organic material substrate prior to depositing the conductive traces, wherein the step of preparing includes cleaning the organic material substrate with a lint-free wipe using ethanol or isopropyl alcohol.

4. The method of claim 1, wherein the additive deposition process can be selected from the group of aerosol deposition, screen-printing, extrusion/direct-write, inkjet printing, gravure printing, flexographic printing, electrohydrodynamic (EHD) printing, laser-induced forward transfer (LIFT), and combinations thereof.

5. The method of claim 1, wherein the step of depositing the conductive traces utilizes a conductive compound, and wherein the conductive compound is selected from the group of metal particle compositions and liquid metal compositions.

6. The method of claim 5, wherein the conductive compound is a metal particle composition and wherein the metal particle of the metal particle composition is selected from the group of gold, silver, platinum, copper, nickel, carbon, two-dimensional inorganic compounds, including transition metal carbides, carbonitrides and nitrides (MXenes), and combinations thereof.

7. The method of claim 5, wherein the conductive compound is a liquid metal composition selected from the group of eutectic gallium-indium, Galinstan, and combinations thereof.

8. The method of claim 1, wherein the step of heat-treating the conductive traces is performed using heat-producing equipment selected from the group of an oven, a hot plate, a heat press, a laminator, a UV light, and combined uses thereof.

9. The method of claim 1, wherein the dielectric material is selected from the group of urethane, silicone, acrylic compounds, epoxy compounds, and combinations thereof and wherein the step of heat-treating the dielectric material utilizes a method selected from the group of UV light curing, drying over time in ambient air, placing the substrate into a temperature-controlled oven, and combinations thereof.

10. The method of claim 1, wherein the step of depositing conductive traces also includes depositing of at least one conductive pad through the additive deposition process and wherein the step of heat-treating the conductive traces also includes heat-treating the at least one conductive pad to create at least one heat-treated conductive pad.

11. The method of claim 1, wherein if a dual layered circuit board is desired, then the substrate is flipped over to expose a bottom portion of the substrate, and step b. through step e. is repeated.

12. The method of claim 11, wherein the non-dielectric material containing area also includes portions wherein at least one via may be created.

13. The method of claim 12, further including the steps of filling in the at least one via with a conductive material, wherein the conductive material is selected from the group of metal particle compositions and liquid metal compositions, and curing the conductive material utilized to fill in the at least one via.

14. The method of claim 13, further comprising the step of depositing a solder mask layer over the conductive traces through the additive deposition process and curing the solder mask, wherein the solder mask layer includes a solder mask ink or encapsulant selected from the group of urethane, silicone, acrylic compounds, epoxy compounds, and combinations thereof.

15. The method of claim 1, wherein if a multi-layered circuit board having x layers is desired, then step b. through step e. is repeated x number of times.

16. The method of claim 15, wherein the non-dielectric material containing area also includes portions wherein at least one via may be created.

17. The method of claim 16, further including the steps of filling in the at least one via with a conductive material, wherein the conductive material is selected from the group of metal particle compositions and liquid metal compositions, and curing the conductive material utilized to fill in the at least one via.

18. The method of claim 17, further comprising the step of depositing a solder mask layer over the conductive traces and curing the solder mask, wherein the solder mask layer includes a solder mask ink or encapsulant selected from the group of urethane, silicone, acrylic compounds, epoxy compounds, and combinations thereof.

19. The method of claim 1, further comprising the steps of depositing a dielectric material through the additive deposition process over the organic material substrate and curing the dielectric material; wherein these additional steps take place prior to the step of depositing the conductive traces.

20. The method of claim 4, further comprising the step of affixing a conductive pattern mask, screen mesh, or stencil over the surface of the organic material, prior to deposition of the conductive traces and further comprising the step of affixing a pattern mask, screen mesh, or stencil over the cured conductive traces, prior to deposition of the dielectric material when the additive deposition process is aerosol deposition or screen-printing.
